(19) United States
(12) Patent Application Publication
(10) Pub. No.: US 2026/0284723 A1
(43) Pub. Date: Sep. 24, 2026

(54) CLEANING METHOD FOR SUBSTRATE ACCOMMODATION CONTAINER AND CLEANING APPARATUS FOR SUBSTRATE ACCOMMODATION CONTAINER

(71) Applicants: Kioxia Corporation, Tokyo (JP); SHIBAURA MECHATRONICS CORPORATION, Yokohama-shi Kanagawa (JP)

(72) Inventors: Tae KAMINO, Yokkaichi Mie (JP); Naoki KANDA, Yokkaichi Mie (JP); Jin OTONARI, Yokkaichi Mie (JP); Hiroshi TOMITA, Muko Kyoto (JP); Yukinobu NISHIBE, Yokohama Kanagawa (JP); Yotaro FUKUOKA, Yokohama Kanagawa (JP); Hisaaki MIYASAKO, Yokohama Kanagawa (JP); Junji ISHIHARA, Yokohama Kanagawa (JP)

(73) Assignees: Kioxia Corporation, Tokyo (JP); SHIBAURA MECHATRONICS CORPORATION, Yokohama-shi Kanagawa (JP)

(21) Appl. No.: 19/573,134

(22) Filed: Mar. 20, 2026

(30) Foreign Application Priority Data
Mar. 21, 2025 (JP) 2025-047447

(51) Int. Cl. B08B 9/46; C11D 1/62; F26B 5/04

(52) U.S. Cl. CPC B08B 9/46; C11D 1/62; F26B 5/041; B08B 2209/08

(57) ABSTRACT

According to one embodiment, a cleaning method for a substrate accommodation container includes performing a cleaning process of removing dust adhering to a surface of a substrate accommodation container accommodating a semiconductor substrate by using a solution containing an organic amine. The method further includes performing a rinsing process of removing the solution adhering to the surface of the substrate accommodation container by using a cleaning water. The method further includes performing a draining process of removing water drops of the cleaning water adhering to the surface of the substrate accommodation container. The method further includes performing a drying process of drying the substrate accommodation container.

### CROSS REFERENCE TO RELATED APPLICATIONS

This application is based upon and claims the benefit of priority from the prior Japanese Patent Application No. 2025-47447, filed on Mar 21, 2025, the entire contents of which are incorporated herein by reference.

### FIELD

The embodiments of the present invention relate to a cleaning method for a substrate accommodation container and a cleaning apparatus for a substrate accommodation container.

### BACKGROUND

Conventional cleaning of an FOUP (Front Opening Unified Pod) for accommodating a semiconductor substrate has used pure water or two fluids including pure water and CDA (Clean Dry Air). However, it has been difficult to remove a component chemically bonded to the surface of the FOUP by the conventional cleaning.

### BRIEF DESCRIPTION OF THE DRAWINGS

FIG. 1 is a plan view illustrating a configuration of a semiconductor manufacturing system according to a first embodiment;

FIG. 2 is a cross-sectional view illustrating a first configuration example of a semiconductor manufacturing apparatus according to the first embodiment;

FIG. 3 is a cross-sectional view illustrating a second configuration example of the semiconductor manufacturing apparatus according to the first embodiment;

FIG. 4 is a cross-sectional view illustrating a cleaning apparatus according to the first embodiment;

FIG. 5 is a plan view illustrating the cleaning apparatus according to the first embodiment;

FIG. 6 is a flowchart illustrating an operation example of the semiconductor manufacturing system according to the first embodiment;

FIG. 7 is a flowchart illustrating an operation example of the cleaning apparatus according to the first embodiment;

FIG. 8 is a flowchart illustrating a cleaning method according to a second embodiment; and

FIG. 9 is a flowchart illustrating an operation example of a cleaning apparatus according to a modification of the second embodiment.

### DETAILED DESCRIPTION

According to one embodiment, a cleaning method for a substrate accommodation container includes performing a cleaning process of removing dust adhering to a surface of a substrate accommodation container accommodating a semiconductor substrate by using a solution containing an organic amine. The method further includes performing a rinsing process of removing the solution adhering to the surface of the substrate accommodation container by using a cleaning water. The method further includes performing a draining process of removing water drops of the cleaning water adhering to the surface of the substrate accommodation container. The method further includes performing a drying process of drying the substrate accommodation container.

### First embodiment

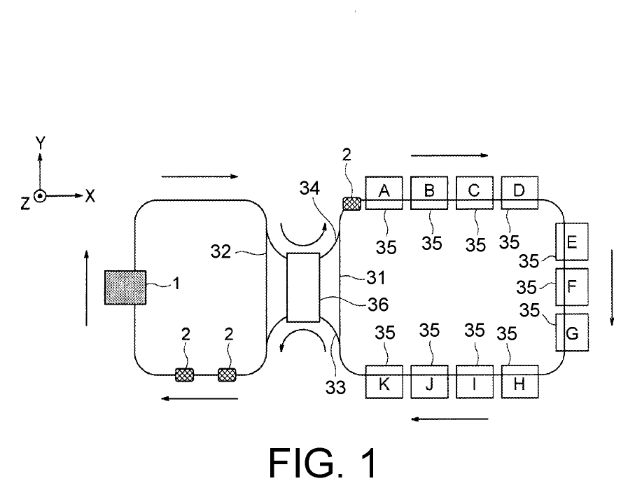

Hereinafter, embodiments of the present invention will be described with reference to the drawings. In FIGS. 1 to 9, the same or similar constituent elements are denoted by like reference signs and redundant explanations thereof are omitted.

FIG. 1 is a plan view illustrating a configuration of a semiconductor manufacturing system according to a first embodiment.

The semiconductor manufacturing system according to the first embodiment includes a cleaning apparatus 1, transportation paths 31 to 34, a plurality of semiconductor manufacturing apparatuses 35, and a substrate handler 36. FIG. 1 further illustrates a plurality of FOUPs 2 transported along the transportation paths 31 to 34. Arrows in FIG. 1 indicate the transportation direction of the FOUP 2. The FOUP 2 is an example of a substrate accommodation container.

The transportation path 31 is a track used when a semiconductor substrate is transported by the FOUP 2. The transportation path 32 is a track used in cleaning of the FOUP 2. Therefore, the transportation path 31 is arranged closely to the semiconductor manufacturing apparatuses 35. The transportation path 32 is arranged closely to the cleaning apparatus 1. When a semiconductor substrate in the FOUP 2 is processed, the FOUP 2 on the transportation path 31 is placed on any of the semiconductor manufacturing apparatuses 35. Meanwhile, when the FOUP 2 is cleaned, the FOUP 2 on the transportation path 32 is placed on the cleaning apparatus 1.

The substrate handler 36 puts a semiconductor substrate into the FOUP 2 and takes the semiconductor substrate out of the FOUP 2. For example, when the FOUP 2 moves from the transportation path 31 to the transportation path 32 via the transportation path 33, the substrate handler 36 takes all semiconductor substrates out of the FOUP 2. Meanwhile, when the FOUP 2 moves from the transportation path 32 to the transportation path 31 via the transportation path 34, the substrate handler 36 puts one or more semiconductor substrates into the FOUP 2.

The semiconductor manufacturing system according to the first embodiment can manufacture a semiconductor device from the semiconductor substrate transported by the FOUP 2. The semiconductor device according to the first embodiment may be processed only in the semiconductor manufacturing system illustrated in FIG. 1 or processed in the semiconductor manufacturing system illustrated in FIG. 1 and another semiconductor manufacturing system.

FIG. 1 exemplifies the semiconductor manufacturing apparatuses 35 represented by reference signs A to K. These semiconductor manufacturing apparatuses 35 include a CVD (Chemical Vapor Deposition) apparatus, a sputtering apparatus, a dry etching apparatus, an annealing apparatus, a CMP (Chemical Mechanical Polishing) apparatus, an ion implantation apparatus, and a substrate cleaning and drying apparatus, for example.

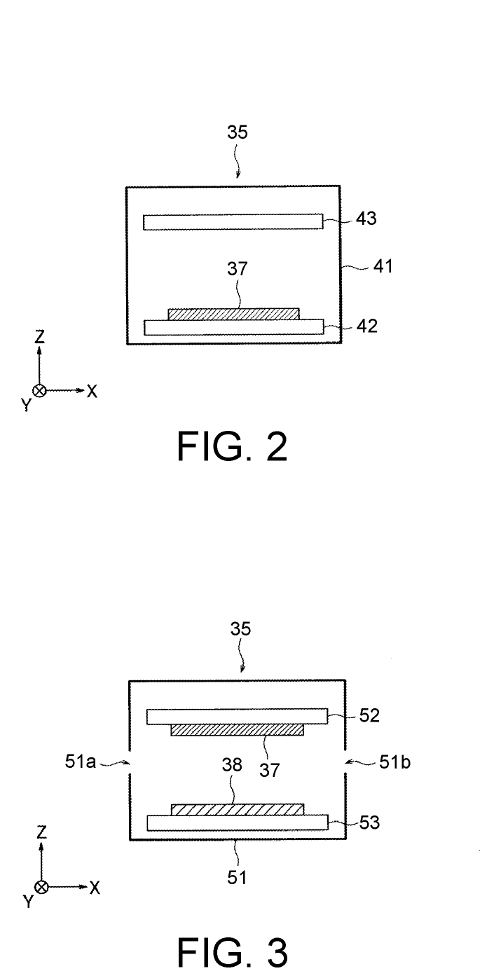

FIG. 2 is a cross-sectional view illustrating a first configuration example of the semiconductor manufacturing apparatus 35 according to the first embodiment.

The semiconductor manufacturing apparatus 35 illustrated in FIG. 2 is a dry etching apparatus. The semiconductor manufacturing apparatus 35 illustrated in FIG. 2 includes a chamber 41, a substrate holder 42, and an ion source 43. The substrate holder 42 holds a semiconductor substrate 37 accommodated in the chamber 41. The ion source 43 irradiates the semiconductor substrate 37 with ions, thereby performing dry etching for the semiconductor substrate 37. When the semiconductor substrate 37 after being dry etched is accommodated in the FOUP 2, the FOUP 2 is easily contaminated by a gas such as fluorine gas or chlorine gas.

FIG. 3 is a cross-sectional view illustrating a second configuration example of the semiconductor manufacturing apparatus 35 according to the first embodiment.

The semiconductor manufacturing apparatus 35 illustrated in FIG. 3 is a sputtering apparatus. The semiconductor manufacturing apparatus 35 illustrated in FIG. 3 includes a camber 51, a substrate holder 52, and a target holder 53. The chamber 51 has an air supply port 51a for supplying a gas for sputtering and an exhaust port 51b for discharging an unnecessary gas. The substrate holder 52 holds the semiconductor substrate 37 accommodated in the chamber 51. The target holder 53 holds a target 38 for sputtering of the semiconductor substrate 37. Since it is desirable to perform sputtering in a state where the semiconductor substrate 37 is clean, it is desirable that the FOUP 2 accommodating the semiconductor substrate 37 before sputtering is also clean.

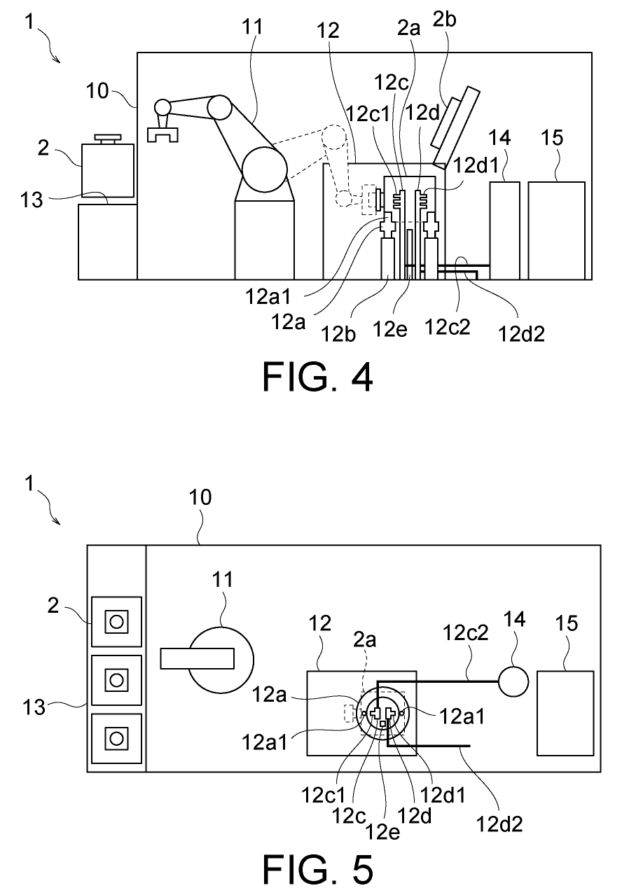

FIG. 4 is a cross-sectional view illustrating the cleaning apparatus 1 according to the first embodiment. FIG. 5 is a plan view illustrating the cleaning apparatus 1 according to the first embodiment. As illustrated in FIGS. 4 and 5, the cleaning apparatus 1 includes a stand 10, a transportation device 11, a cleaning bath 12, a placing table 13, a tank 14, and a controller 15. The transportation device 11, the cleaning bath 12, the tank 14, and the controller 15 are arranged inside the stand 10 in the form of a box. The placing table 13 is arranged outside the box-shaped stand 10.

The placing table 13 is arranged on the transportation path 32. Via the placing table 13, the FOUP 2 is transported to inside of the stand 10 or to outside of the stand 10. More specifically, when the FOUP 2 on the transportation path 32 is placed on the placing table 13, the transportation device 11 transports the FOUP 2 from the placing table 13 to the cleaning bath 12. When processes including a cleaning process described later and the like are completed in the cleaning bath 12, the transportation device 11 transports the FOUP 2 from the cleaning bath 12 to the placing table 13. The transportation device 11 is an articulated robot arm, for example.

The cleaning bath 12 cleans the FOUP 2 in a state where the FOUP 2 is separated into a FOUP body 2a and a door 2b. The cleaning bath 12 includes a holding table 12a, a driver 12b, a first supplier 12c, a second supplier 12d, and a spray 12e. The holding table 12a holds the FOUP body 2a to allow it to rotate around the first supplier 12c and the second supplier 12d.

The holding table 12a has a holding projection 12a1 abutting on the inner wall of the FOUP body 2a. The driver 12b can drive and rotate the holding table 12a. The first supplier 12c includes a first nozzle 12c1 and a first pipe 12c2. The second supplier 12d includes a second nozzle 12d1 and a second pipe 12d2. The first nozzle 12c1 and the second nozzle 12d1 each function as a supply port. In place of the first nozzle 12c1, a hole may be formed in the first supplier 12c itself, and the hole may be used as a supply port. Further, in place of the second nozzle 12d1, a hole may be formed in the second supplier 12d itself, and the hole may be used as a supply port.

The tank 14 stores therein an organic amine solution. The tank 14 can adjust the temperature and/or the concentration of the organic amine solution. The organic amine solution stored in the tank 14 is supplied to the first supplier 12c via the first pipe 12c2. For example, in a cleaning process described later, the first supplier 12c supplies the organic amine solution from the first nozzle 12c1 to the inner wall surface of the FOUP body 2a in a state where the holding table 12a accommodates the FOUP body 2a.

Although the tank 14 is installed in the cleaning apparatus 1 in the first embodiment, a case where the tank 14 is installed around the cleaning apparatus 1 is also included in the present invention as long as the purpose of using the tank 14 is this purpose.

A cleaning water is supplied to the second supplier 12d from a pipe (not illustrated) in the system via the second pipe 12d2. For example, in a rinsing process described later, the second supplier 12d supplies a cleaning water to the inner wall surface of the FOUP body 2a from the second nozzle 12d1 in a state where the holding table 12a accommodates the FOUP body 2a.

For example, in a draining process described later, the driver 12b drives and rotates the holding table 12a holding the FOUP body 2a. In this case, the driver 12b functions as a draining section.

For example, in a drying process described later, the spray 12e sprays CDA onto the inner wall surface of the FOUP body 2a. In this case, the spray 12e functions as a drier.

The controller 15 controls the transportation device 11, the cleaning bath 12, and the tank 14.

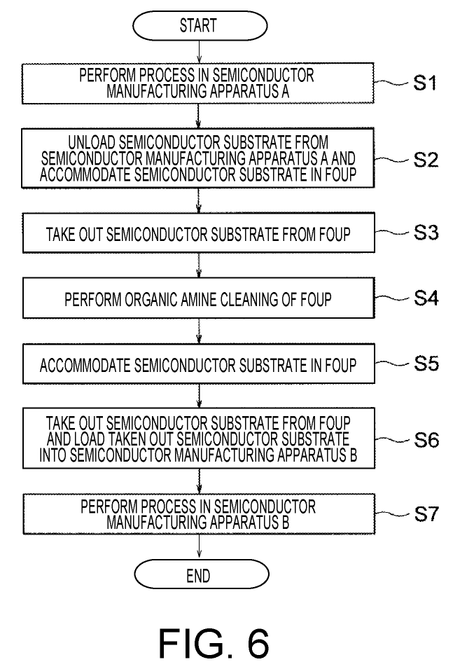

FIG. 6 is a flowchart illustrating an operation example of the semiconductor manufacturing system according to the first embodiment.

FIG. 6 illustrates a flow in which the semiconductor substrate 37 in a certain FOUP 2 is processed by any of the semiconductor manufacturing apparatuses 35, and thereafter the semiconductor substrate 37 in that FOUP 2 is processed by another semiconductor manufacturing apparatus 35. In FIG. 6, the former apparatus is called the semiconductor manufacturing apparatus 35 represented by the reference sign A (hereinafter, the "semiconductor manufacturing apparatus A"), and the latter apparatus is called the semiconductor manufacturing apparatus 35 represented by the reference sign B (hereinafter, the "semiconductor manufacturing apparatus B").

In this case, it may be desirable to clean the FOUP 2 between the process in the semiconductor manufacturing apparatus A and the process in the semiconductor manufacturing apparatus B. For example, in a case where the semiconductor manufacturing apparatus A is a dry etching apparatus and the semiconductor manufacturing apparatus B is a sputtering apparatus, the FOUP 2 is easily contaminated after the process in the semiconductor manufacturing apparatus A although it is desirable that the FOUP 2 is clean before the process in the semiconductor manufacturing apparatus B. FIG. 6 illustrates the flow for dealing with such contamination.

First, the semiconductor substrate 37 is processed in the semiconductor manufacturing apparatus A (Step S1), and thereafter the semiconductor substrate 37 is unloaded from the semiconductor manufacturing apparatus A. After the semiconductor substrate 37 is unloaded, the unloaded semiconductor substrate 37 is accommodated in the FOUP 2 (Step S2). After the semiconductor substrate 37 is accommodated in the FOUP 2, the FOUP 2 is transported to the substrate handler 36. After the FOUP 2 is transported to the substrate handler 36, the semiconductor substrate 37 is taken out of the FOUP 2 by the substrate handler 36 (Step S3). After the semiconductor substrate 37 is taken out, the FOUP 2 is cleaned with an organic amine by the cleaning apparatus 1 (Step S4).

After the FOUP 2 is cleaned with the organic amine, the FOUP 2 is transported to the substrate hander 36. After the FOUP 2 is transported to the substrate handler 36, the semiconductor substrate 37 is accommodated in the FOUP 2 by the substrate handler 36 (Step S5). The semiconductor substrate 37 accommodated at Step S5 may be the same as the semiconductor substrate 37 taken out at Step S3 or different from the semiconductor substrate 37 taken out at Step S3. After the semiconductor substrate 37 is accommodated in the FOUP 2, the FOUP 2 is moved to the vicinity of the semiconductor manufacturing apparatus B. After the FOUP 2 is moved to the vicinity of the semiconductor manufacturing apparatus B, the semiconductor substrate 37 is taken out of the FOUP 2, and the taken out semiconductor substrate 37 is loaded into the semiconductor manufacturing apparatus B (Step S6). After the semiconductor substrate 37 is loaded into the semiconductor manufacturing apparatus B, the semiconductor substrate 37 is processed in the semiconductor manufacturing apparatus B (Step S7).

According to the first embodiment, even in a case where the semiconductor manufacturing apparatus 35 that can easily contaminate the FOUP 2 is included in the semiconductor manufacturing system, the FOUP 2 can be kept clean.

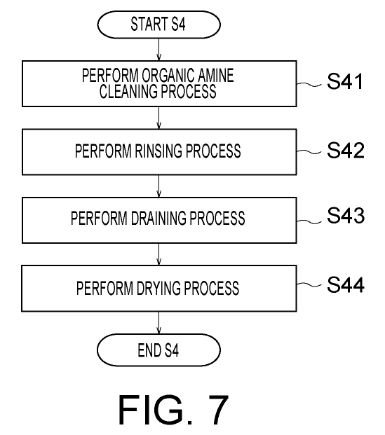

FIG. 7 is a flowchart illustrating an operation example of the cleaning apparatus 1 according to the first embodiment.

In organic amine cleaning of the FOUP 2 illustrated in FIG. 6 (Step S4), an organic amine cleaning process of removing dust adhering to the surface of the FOUP 2 is performed by using an organic amine solution containing an organic amine first as illustrated in FIG. 7 (Step S41). Using the organic amine solution that is an alkaline solution enables effective removal of silicon dust. Further, by preventing electrostatic charge, it is possible to prevent the dust from adhering to the surface of the FOUP 2 again.

More specifically, the organic amine cleaning process may be performed by using a solution containing a quaternary ammonium as the organic amine solution. Using the solution containing a quaternary ammonium enables more effective removal of dust.

Further specifically, the organic amine cleaning process may be performed by using a solution containing TMAH (tetramethylammonium hydroxide) or CHOLINE (trimethyl-2-hydroxyethylammonium hydroxide) as the quaternary ammonium. Using TMAH or CHOLINE enables more effective removal of dust.

It is preferable that the temperature of the organic amine solution used in the organic amine cleaning process is higher than 20°C and lower than 70°C. More specifically, the organic amine cleaning process is preferably performed by using the organic amine solution at a temperature of around 30°C, for example. In this case, the organic amine solution may be heated to around 30°C by means of a heating mechanism arranged on the upstream side of the cleaning bath 12. By using the organic amine solution at a temperature of around 30°C, dust can be effectively removed.

Further, the organic amine cleaning process may be performed by using the organic amine solution with an organic amine concentration of 0.1% or more and 1.0% or less. In this case, the organic amine solution may be mixed with pure water by means of a dilution unit arranged on the upstream side of the cleaning bath 12 to be diluted. In a case where the organic amine concentration is less than 0.1%, the dust removal effect is insufficient. In a case where the organic amine concentration exceeds 1.0%, the cost becomes high.

The organic amine cleaning process may be performed while the FOUP 2 is rotated at a first rotation speed. The first rotation speed is 50 rpm or less, for example. In this case, the holding table 12a holding the FOUP 2 may be rotated by the driver 12b provided in the cleaning bath 12. By rotating the FOUP 2 at a rotation speed of 50 rpm or less, dust can be removed more effectively.

The organic amine cleaning process may be performed by using a mixed fluid obtained by mixing the organic amine solution and a gas. In this case, the mixed fluid of the organic amine solution and the gas may be produced by using a mixing box arranged on the upstream side of the cleaning bath 12, and the produced mixed fluid may be sprayed to the surface of the FOUP 2 from a nozzle. Using the mixed fluid can increase the spray impact of the organic amine solution and enables more effective removal of dust.

After the organic amine cleaning process is performed, a rinsing process is performed which removes the organic amine solution adhering to the surface of the FOUP 2 by using a cleaning water (Step S42).

The rinsing process may be performed by spraying a second mixed fluid obtained by mixing pure water as the cleaning water and a gas from a nozzle to the surface of the FOUP 2. Using the second mixed fluid enables the rinsing process to be performed effectively.

After the rinsing process is performed, a draining process of removing water drops of the cleaning water adhering to the surface of the FOUP 2 is performed (Step S43).

The draining process may be performed by rotating the holding table 12a holding the FOUP 2 by the driver 12b described above. In this case, the FOUP 2 may be rotated at a second rotation speed larger than the first rotation speed by the driver 12b. The second rotation speed is 100 rpm or more, for example. That is, the draining process may be performed while the FOUP 2 is rotated at a rotation speed (the second rotation speed) more than twice the rotation speed (the first speed) of the FOUP 2 in the cleaning process. Alternatively, the draining process may be performed by spraying CDA to the FOUP 2 in the cleaning bath 12. In this case, a mechanism that sprays the CDA to the FOUP 2 functions as a draining section.

After the draining process is performed, a drying process of drying the FOUP 2 is performed (Step S44).

The drying process may be performed by spraying CDA to the FOUP 2 in the cleaning bath 12 by means of the spray 12e as a drier. In a case where the draining process is performed by spraying the CDA to the FOUP 2 in the cleaning bath 12, the draining process and the drying process may be performed in an integrated manner. Further, the spray 12e may be made to function as both the draining section and the drier. Alternatively, the drying process may be performed by heating the FOUP 2 under vacuum. In this case, a mechanism of heating the FOUP 2 under vacuum functions as the drier.

As described above, according to the first embodiment, using an organic amine solution enables appropriate cleaning of the FOUP 2.

### Second embodiment

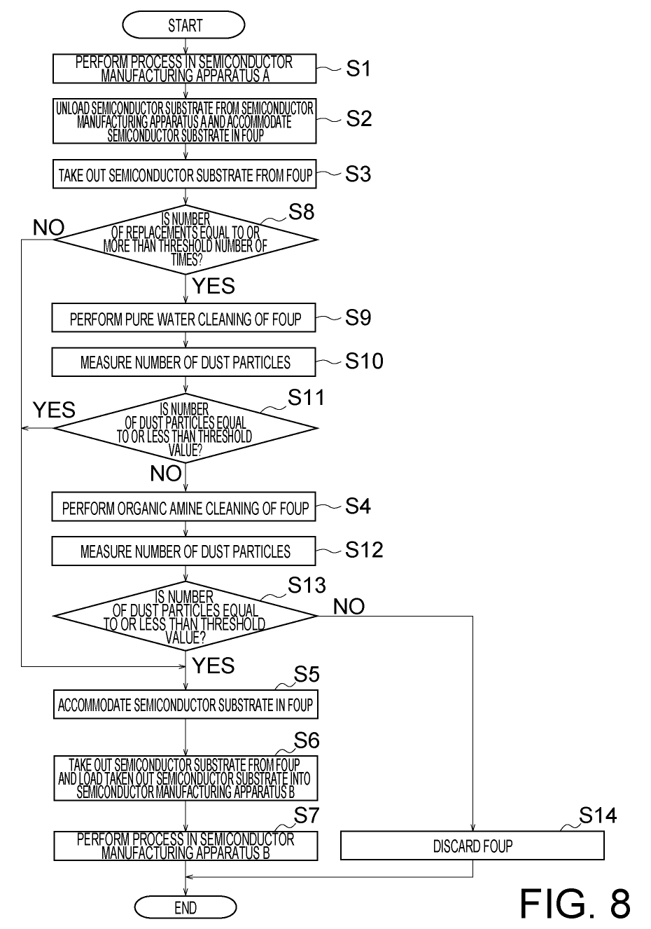

Next, a second embodiment in which organic amine cleaning is performed in accordance with the number of dust particles after pure water cleaning is described, focusing on differences from the first embodiment. FIG. 8 is a flowchart illustrating a cleaning method according to the second embodiment.

As illustrated in FIG. 8, in the second embodiment, after the semiconductor substrate 37 is taken out of the FOUP 2 (Step S3), in a case where the number of replacements of the semiconductor substrate 37 with respect to the FOUP 2 is equal to or more than a threshold number of times (YES at Step S8), pure water cleaning that removes dust adhering to the surface of the FOUP 2 by using pure water is performed (Step S9). The pure water cleaning is an example of a second cleaning process. The threshold number of times may be three times.

Meanwhile, in a case where the number of replacements of the semiconductor substrate 37 is not equal to or more than the threshold number of times (NO at Step S8), the semiconductor substrate 37 is accommodated in the FOUP 2 (Step S5).

After the pure water cleaning is performed, the number of dust particles on the surface of the FOUP 2 is measured by using a dust-particle measuring instrument arranged in the cleaning apparatus 1 (Step S10).

In a case where the number of dust particles is equal to or less than a threshold value after the measurement of the number of dust particles (YES at Step S11), the semiconductor substrate 37 is accommodated in the FOUP 2 (Step S5). The threshold value may be 500.

Meanwhile, in a case where the number of dust particles is not equal to or less than the threshold value (NO at Step S11), organic amine cleaning of the FOUP 2 is performed (Step S4).

After the organic amine cleaning is performed, the number of dust particles on the surface of the FOUP 2 is measured again by using the dust-particle measuring instrument (Step S12).

In a case where the number of dust particles is equal to or less than the threshold value after the measurement of the number of dust particles (YES at Step S13), the semiconductor substrate 37 is accommodated in the FOUP 2 (Step S5).

Meanwhile, in a case where the number of dust particles is not equal to or less than the threshold value (NO at Step S13), the FOUP 2 is discarded (Step S14).

According to the second embodiment, organic amine cleaning is performed in a case where the number of dust particles after pure water cleaning is performed exceeds a threshold value. Accordingly, the organic amine cleaning can be performed only for dust that is difficult to remove. In addition, the usage of the organic amine solution can be reduced.

### Modification

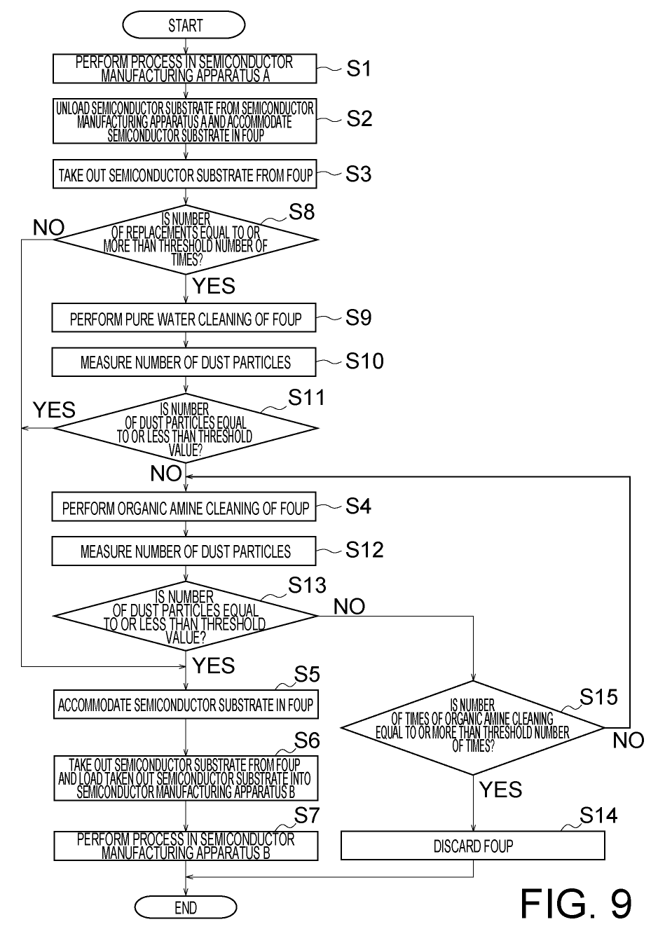

Next, a modification of the second embodiment in which, in a case where the number of dust particles is not equal to or less than a threshold value, organic amine cleaning is repeated until a threshold number of times is described, focusing on differences from the embodiments described above. FIG. 9 is a flowchart illustrating an operation example of the cleaning apparatus 1 according to the modification of the second embodiment. In FIG. 8, the example has been described in which in a case where the number of dust particles is not equal to or less than a threshold value (NO at Step S13) as a result of measurement of the number of dust particles (Step S12) after organic amine cleaning, the FOUP 2 is discarded.

Meanwhile, in the example illustrated in FIG. 9, in a case where the number of dust particles is not equal to or less than a threshold value (NO at Step S13) as a result of measurement of the number of dust particles (Step S12) after organic amine cleaning, and the number of times of organic amine cleaning is equal to or more than a threshold number of times (YES at Step S15), the FOUP 2 is discarded (Step S14). On the other hand, in a case where the number of dust particles is not equal to or less than the threshold value (NO at Step S13) as a result of the measurement of the number of dust particles (Step S12) after the organic amine cleaning, and the number of times of organic amine cleaning is not equal to or more than the threshold number of times (NO at Step S15), the organic amine cleaning is repeated (Step S4). According to the example illustrated in FIG. 9, the FOUP 2 is discarded only when the number of dust particles is not equal to or less than the threshold value after the organic amine cleaning is performed the threshold number of times. Accordingly, the number of discarded FOUPs 2 can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cleaning method for a substrate accommodation container, comprising:
performing a cleaning process of removing dust adhering to a surface of a substrate accommodation container for accommodating a semiconductor substrate by using a solution containing an organic amine;
performing a rinsing process of removing the solution adhering to the surface of the substrate accommodation container by using a cleaning water;
performing a draining process of removing water drops of the cleaning water adhering to the surface of the substrate accommodation container; and
performing a drying process of drying the substrate accommodation container.

2. The method of claim 1, wherein the cleaning process is performed by using the solution containing a quaternary ammonium as the organic amine.

3. The method of claim 2, wherein the cleaning process is performed by using the solution containing TMAH (tetramethylammonium hydroxide) or CHOLINE (trimethyl-2-hydroxyethylammonium hydroxide) as the quaternary ammonium.

4. The method of claim 1, wherein the cleaning process is performed by using the solution with a concentration of the organic amine being 0.1% or more and 1.0% or less.

5. The method of claim 1, wherein the cleaning process is performed while the organic amine is heated to 30°C or more.

6. The method of claim 1, wherein the cleaning process is performed while rotating the substrate accommodation container at a rotation speed of 50 rpm or less.

7. The method of claim 6, wherein the draining process is performed while rotating the substrate accommodation container at a rotation speed more than twice the rotation speed of the substrate accommodation container in the cleaning process.

8. The method of claim 1, wherein the drying process is performed by heating the substrate accommodation container under vacuum.

9. The method of claim 1, wherein the cleaning process is performed by using a mixed fluid obtained by mixing the solution and a gas.

10. The method of claim 1, wherein the rinsing process is performed by using a second mixed fluid obtained by mixing pure water as the cleaning water and a gas.

11. The method of claim 1, further comprising:
performing a second cleaning process of removing the dust adhering to the surface of the substrate accommodation container by using pure water; and
performing a measurement process of measuring number of particles of the dust adhering to the surface of the substrate accommodation container after the second cleaning process, wherein
the cleaning process using the solution is performed in a case where the measured number of particles of the dust exceeds a threshold value.

12. A cleaning apparatus for a substrate accommodation container, comprising:
a tank capable of storing an organic amine therein;
a holding table capable of holding a substrate accommodation container accommodating a semiconductor substrate;
a first supplier connected to the tank, having a first supply port, and configured to be capable of supplying the organic amine to a surface of the substrate accommodation container from the first supply port;
a second supplier having a second supply port and configured to be capable of supplying a cleaning water from the second supply port to the surface of the substrate accommodation container;
a draining section configured to remove water drops from the surface of the substrate accommodation container; and
a drier configured to dry the surface of the substrate accommodation container.
